(19) United States
(12) Patent Application Publication
(10) Pub. No.: US 2016/0153856 A1
(43) Pub. Date: Jun. 2, 2016

(54) ELECTRONIC DEVICE, PHYSICAL QUANTITY SENSOR, PRESSURE SENSOR, VIBRATOR, ALTIMETER, ELECTRONIC APPARATUS, AND MOVING OBJECT

(71) Applicant: Seiko Epson Corporation, Tokyo (JP)

(72) Inventor: Kazuya HAYASHI, Chino (JP)

(21) Appl. No.: 14/951,996

(22) Filed: Nov. 25, 2015

(30) Foreign Application Priority Data
Nov. 28, 2014 (JP) 2014-242323

(51) Int. Cl. G01L 9/00; H03H 9/24; G01C 5/06

(52) U.S. Cl. CPC G01L 9/0054; G01C 5/06; H03H 9/2463

(57) ABSTRACT

A physical quantity sensor includes a substrate, a piezoresistive element that is arranged on one face side of the substrate, a wall portion that is arranged to surround the piezoresistive element on the one face side of the substrate in a plan view of the substrate, a ceiling portion that is arranged on the opposite side of the wall portion from the substrate and constitutes a cavity portion with the wall portion, and an inside beam portion that is arranged on the substrate side of the ceiling portion and includes a material of which the thermal expansion rate is smaller than the thermal expansion rate of the ceiling portion.

### CROSS REFERENCE

This application claims the benefit of Japanese Patent Application No. 2014-242323, filed on Nov. 28, 2014. The disclosure of the prior application is hereby incorporated by reference herein in its entirety.

### BACKGROUND

1. Technical Field

The present invention relates to an electronic device, a physical quantity sensor, a pressure sensor, a vibrator, an altimeter, an electronic apparatus, and a moving object.

2. Related Art

There is known an electronic device that includes a cavity portion formed by using a semiconductor manufacturing process (for example, refer to JP-A-2008-114354). An example of such an electronic device is the electronic device that is in accordance with JP-A-2008-114354. The electronic device, as disclosed in JP-A-2008-114354, is provided with a substrate, a functional structure that constitutes a functional element formed on the substrate, and a cladding structure that defines a cavity portion in which the functional structure is arranged. The cladding structure includes a laminated structure of an interlayer insulating film and an interconnect layer that is formed on the substrate like surrounding the periphery of the cavity portion. An upper cladding portion of the cladding structure that covers the cavity portion from above is configured of apart of the interconnect layer that is arranged above the functional structure.

The electronic device according to JP-A-2008-114354, however, has a problem in that the upper cladding portion may bend toward the substrate and collapse depending on the height, width, or the like of the upper cladding portion because the upper cladding portion (ceiling portion) is thin. This is because it is difficult to increase the thickness of the upper cladding portion. Even if the thickness of the upper cladding portion can be increased, simply increasing the thickness may lead to an increase in the mass of the upper cladding portion, and the strength of the upper cladding portion cannot be increased efficiently.

### SUMMARY

An advantage of some aspects of the invention is to provide an electronic device and a physical quantity sensor having excellent reliability and to provide a pressure sensor, a vibrator, an altimeter, an electronic apparatus, and a moving object provided with the electronic device.

Such an advantage is accomplished by the following application examples.

### APPLICATION EXAMPLE 1

An electronic device according to this application example includes a substrate, a functional element that is arranged on one face side of the substrate, a wall portion that is arranged to surround the functional element on the one face side of the substrate in a plan view of the substrate, a ceiling portion that is arranged on the opposite side of the wall portion from the substrate and constitutes an inner space with the wall portion, and an inside beam portion that is arranged on the substrate side of the ceiling portion, has a part that overlaps with the ceiling portion in a plan view, and includes a material of which the thermal expansion rate is smaller than the thermal expansion rate of the ceiling portion.

According to such an electronic device, the ceiling portion can be reinforced by the inside beam portion. Particularly, since the inside beam portion supports the ceiling portion on the substrate side of the ceiling portion, that is, on the side onto which the ceiling portion collapses, the ceiling portion can be efficiently reinforced by the inside beam portion. Thus, it is possible to realize the compatibility of the strength and weight reduction of a structure that includes the ceiling portion and the configuration which reinforces the ceiling portion. In addition, since the inside beam portion includes a material of which the thermal expansion rate is smaller than the thermal expansion rate of the ceiling portion, it is possible to reduce the thermal expansion of the ceiling portion with the inside beam portion and to reduce bending (collapse) of the ceiling portion due to thermal expansion. Accordingly, it is possible to reduce the collapse of the ceiling portion and in turn, to increase the reliability of the electronic device.

### APPLICATION EXAMPLE 2

It is preferable that the electronic device according to the application example further includes a frame portion that is connected to an end portion of the inside beam portion and includes the same material as the inside beam portion.

With this configuration, it is possible to integrally form the inside beam portion and the frame portion together at the same time into one same layer. Thus, the inside beam portion can have excellent mechanical strength. In addition, the frame portion can be used in other situations such as an anti-reflective film in the case of exposing a photoresist to light.

### APPLICATION EXAMPLE 3

In the electronic device according to the application example, it is preferable that the ceiling portion includes aluminum, and the inside beam portion includes titanium or a titanium compound.

With this configuration, it is possible to form the ceiling portion that has excellent air tightness comparatively simply and accurately. In addition, the inside beam portion can be formed by using an anti-reflective film that is used in an exposure process of photolithography. In addition, titanium or titanium compounds have a smaller thermal expansion rate than aluminum.

### APPLICATION EXAMPLE 4

In the electronic device according to the application example, it is preferable that the ceiling portion includes a first layer, a second layer that is arranged on the opposite side of the first layer from the substrate and includes the same material as the first layer, and an intermediate layer that is arranged between the first layer and the second layer and includes a material of which the thermal expansion rate is smaller than the thermal expansion rates of the first layer and the second layer.

With this configuration, a release hole can be disposed in the first layer, and the release hole can be closed by the second layer. In addition, the intermediate layer can be formed by using a film (for example, an anti-reflective film) that is disposed on the first layer during manufacturing. It is also possible to reduce the thermal expansion of the first layer and the second layer with the intermediate layer.

### APPLICATION EXAMPLE 5

It is preferable that the electronic device according to the application example further includes an outside beam portion that is arranged between the intermediate layer and the second layer at a position where the outside beam portion overlaps with at least apart of the inside beam portion in a plan view.

With this configuration, the ceiling portion can also be reinforced by the outside beam portion. In addition, since the outside beam portion overlaps with the inside beam portion in a plan view, it is possible to arrange a release hole in the ceiling portion with comparatively high density of arrangement without separating working of the inside beam portion and the outside beam portion.

### APPLICATION EXAMPLE 6

In the electronic device according to the application example, it is preferable that the substrate includes a diaphragm portion that is disposed at a position where the diaphragm portion overlaps with the ceiling portion in a plan view and that is deformed in a flexural manner by the reception of pressure, and the functional element is a sensor element that outputs an electrical signal from strain.

With this configuration, the electronic device can be used in a pressure sensor.

### APPLICATION EXAMPLE 7

A physical quantity sensor according to this application example includes a substrate that includes a diaphragm portion which is deformed in a flexural manner by the reception of pressure, a sensor element that is arranged on one face side of the diaphragm portion, a wall portion that is arranged to surround the sensor element on the one face side of the substrate in a plan view of the substrate, a ceiling portion that is arranged on the opposite side of the wall portion from the substrate and constitutes an inner space with the wall portion, and an inside beam portion that is arranged on the substrate side of the ceiling portion and includes a material of which the thermal expansion rate is smaller than the thermal expansion rate of the ceiling portion.

According to such a physical quantity sensor, the ceiling portion can be reinforced by the inside beam portion. Particularly, since the inside beam portion supports the ceiling portion on the substrate side of the ceiling portion, that is, on the side onto which the ceiling portion collapses, the ceiling portion can be efficiently reinforced by the inside beam portion. Thus, it is possible to realize the compatibility of the strength and weight reduction of a structure that includes the ceiling portion and the configuration which reinforces the ceiling portion. In addition, since the inside beam portion includes a material of which the thermal expansion rate is smaller than the thermal expansion rate of the ceiling portion, it is possible to reduce the thermal expansion of the ceiling portion with the inside beam portion and to reduce bending (collapse) of the ceiling portion due to thermal expansion. Accordingly, it is possible to reduce the collapse of the ceiling portion and in turn, to increase the reliability of the physical quantity sensor.

### APPLICATION EXAMPLE 8

A pressure sensor according to this application example includes the electronic device according to the application example.

With this configuration, it is possible to provide the pressure sensor that has excellent reliability.

### APPLICATION EXAMPLE 9

A vibrator according to this application example includes the electronic device according to the application example.

With this configuration, it is possible to provide the vibrator that has excellent reliability.

### APPLICATION EXAMPLE 10

An altimeter according to this application example includes the electronic device according to the application example.

With this configuration, it is possible to provide the altimeter that has excellent reliability.

### APPLICATION EXAMPLE 11

An electronic apparatus according to this application example includes the electronic device according to the application example.

With this configuration, it is possible to provide the electronic apparatus that includes the electronic device having excellent reliability.

### APPLICATION EXAMPLE 12

A moving object according to this application example includes the electronic device according to the application example.

With this configuration, it is possible to provide the moving object that includes the electronic device having excellent reliability.

### BRIEF DESCRIPTION OF THE DRAWINGS

The invention will be described with reference to the accompanying drawings, wherein like numbers reference like elements.

FIG. 1 is a sectional view illustrating an electronic device (physical quantity sensor) that is in accordance with a first embodiment of the invention.

FIG. 2 is a plan view illustrating the arrangement of piezoresistive elements (sensor elements) and a wall portion of the physical quantity sensor illustrated in FIG. 1.

FIGS. 3A and 3B are diagrams for describing the action of the physical quantity sensor illustrated in FIG. 1: FIG. 3A is a sectional view illustrating the physical quantity sensor in an increased pressure state, and FIG. 3B is a plan view illustrating the physical quantity sensor in the increased pressure state.

FIG. 4 is a plan view illustrating the arrangement of an inside beam portion (reinforcing portion) of the physical quantity sensor illustrated in FIG. 1.

FIG. 5 is a partial enlarged sectional view of the physical quantity sensor illustrated in FIG. 1.

FIGS. 6A to 6D are diagrams illustrating a process of manufacturing the physical quantity sensor illustrated in FIG. 1.

FIGS. 7A to 7D are diagrams illustrating the process of manufacturing the physical quantity sensor illustrated in FIG. 1.

FIGS. 8A to 8C are diagrams illustrating the process of manufacturing the physical quantity sensor illustrated in FIG. 1.

FIG. 9 is a plan view illustrating the arrangement of an inside beam portion (reinforcing portion) of a physical quantity sensor that is in accordance with a second embodiment of the invention.

FIG. 10 is a plan view illustrating the arrangement of an inside beam portion (reinforcing portion) of an electronic device (physical quantity sensor) that is in accordance with a third embodiment of the invention.

FIG. 11 is a plan view illustrating the arrangement of an inside beam portion (reinforcing portion) of an electronic device (physical quantity sensor) that is in accordance with a fourth embodiment of the invention.

FIG. 12 is a plan view illustrating the arrangement of an inside beam portion (reinforcing portion) of an electronic device (physical quantity sensor) that is in accordance with a fifth embodiment of the invention.

FIG. 13 is a sectional view illustrating an electronic device (vibrator) that is in accordance with a sixth embodiment of the invention.

FIG. 14 is a sectional view illustrating an example of a pressure sensor according to the invention.

FIG. 15 is a perspective view illustrating an example of an altimeter according to the invention.

FIG. 16 is a front view illustrating an example of an electronic apparatus according to the invention.

FIG. 17 is a perspective view illustrating an example of a moving object according to the invention.

### DESCRIPTION OF EXEMPLARY EMBODIMENTS

Hereinafter, an electronic device, a physical quantity sensor, a pressure sensor, a vibrator, an altimeter, an electronic apparatus, and a moving object according to the invention will be described in detail on the basis of each embodiment illustrated in the appended drawings.

### 1. Physical Quantity Sensor

### First Embodiment

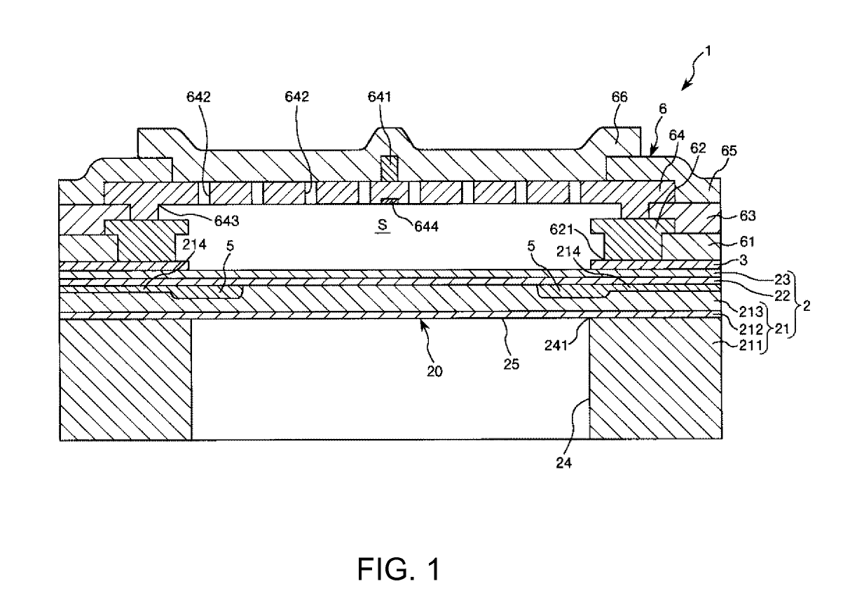

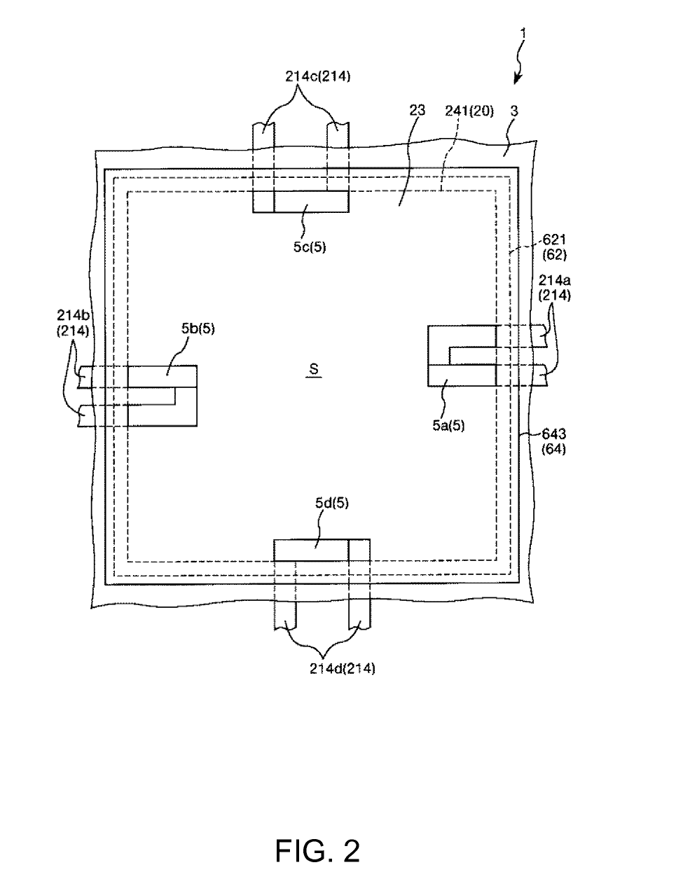

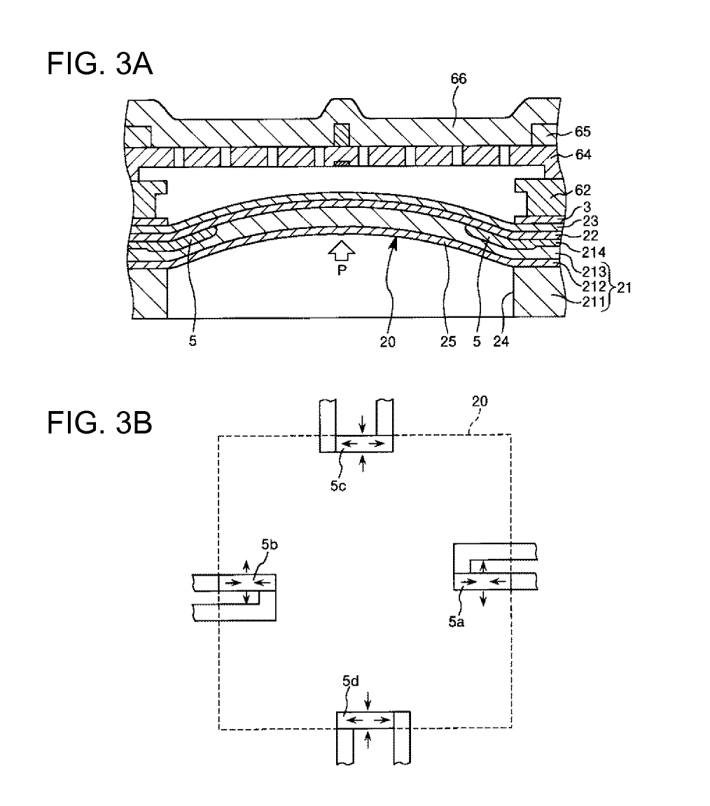

FIG. 1 is a sectional view illustrating an electronic device (physical quantity sensor) that is in accordance with a first embodiment of the invention. FIG. 2 is a plan view illustrating the arrangement of piezoresistive elements (sensor elements) and a wall portion of the physical quantity sensor illustrated in FIG. 1. FIGS. 3A and 3B are diagrams for describing the action of the physical quantity sensor illustrated in FIG. 1 in which FIG. 3A is a sectional view illustrating the physical quantity sensor in an increased pressure state, and FIG. 3B is a plan view illustrating the physical quantity sensor in the increased pressure state. Hereinafter, the upper part of FIG. 1 will be referred to as “up” and the lower part as “down” for convenience of description.

A physical quantity sensor 1 illustrated in FIG. 1 is provided with a substrate 2, a plurality of piezoresistive elements 5 (sensor elements), a laminated structure 6, and an intermediate layer 3. The substrate 2 includes a diaphragm portion 20. The plurality of piezoresistive elements 5 is functional elements arranged in the diaphragm portion 20. The laminated structure 6 forms a cavity portion S (inner space) along with the substrate 2. The intermediate layer 3 is arranged between the substrate 2 and the laminated structure 6.

Hereinafter, each portion constituting the physical quantity sensor 1 will be described in order.

### Substrate

The substrate 2 includes a semiconductor substrate 21, an insulating film 22, and an insulating film 23. The insulating film 22 is disposed on one face of the semiconductor substrate 21. The insulating film 23 is disposed on the opposite face of the insulating film 22 from the semiconductor substrate 21.

The semiconductor substrate 21 is an SOI substrate in which a silicon layer 211 (handle layer), a silicon oxide layer 212 (box layer), and a silicon layer 213 (device layer) are laminated in this order. The silicon layer 211 is configured of monocrystalline silicon. The silicon oxide layer 212 is configured of a silicon oxide film. The silicon layer 213 is configured of monocrystalline silicon. The semiconductor substrate 21 is not limited to an SOI substrate and may be one of other semiconductor substrates such as a monocrystalline silicon substrate.

The insulating film 22 is, for example, a silicon oxide film and has insulating properties. The insulating film 23 is, for example, a silicon nitride film, has insulating properties, and has tolerance to etching liquid that includes hydrofluoric acid. By interposing the insulating film 22 (silicon oxide film) between the semiconductor substrate 21 (silicon layer 213) and the insulating film 23 (silicon nitride film), the insulating film 22 can alleviate the propagation of stress generated in the deposition of the insulating film 23 to the semiconductor substrate 21. The insulating film 22 can also be used as an inter-element separating film when the semiconductor substrate 21 and a semiconductor circuit thereabove are formed. Materials constituting the insulating films 22 and 23 are not limited to the above example. In addition, either the insulating film 22 or the insulating film 23 may not be provided if necessary.

The patterned intermediate layer 3 is arranged on such an insulating film 23 of the substrate 2. The intermediate layer 3 is formed to surround the periphery of the diaphragm portion 20 in a plan view. The intermediate layer 3 forms a stepped portion between the upper face of the intermediate layer 3 and the upper face of the substrate 2 toward the center (inside) of the diaphragm portion 20. The stepped portion has the same thickness as the intermediate layer. Accordingly, it is possible to concentrate stress on apart of the diaphragm portion 20 that is the boundary between the diaphragm portion 20 and the stepped portion when the diaphragm portion 20 is deformed in a flexural manner by the reception of pressure. Thus, detection sensitivity can be improved by arranging the piezoresistive elements 5 at the boundary part (or near the boundary part).

The intermediate layer 3 is configured of, for example, monocrystalline silicon, polycrystalline silicon (polysilicon), or amorphous silicon. The intermediate layer 3 may be configured by, for example, doping (through diffusion or implantation) monocrystalline silicon, polycrystalline silicon (polysilicon), or amorphous silicon with an impurity such as phosphorus or boron. Since the intermediate layer 3 has conductivity in this case, apart of the intermediate layer 3 can be used as the gate electrode of an MOS transistor when, for example, the MOS transistor is formed on the substrate 2 outside the cavity portion S. In addition, a part of the intermediate layer 3 can be used as an interconnect.

The diaphragm portion 20 that is thinner than the part therearound and that is deformed in a flexural manner by the reception of pressure is disposed in such a substrate 2. The diaphragm portion 20 is formed by disposing a bottomed recessed portion 24 on the lower face of the semiconductor substrate 21. That is, the diaphragm portion 20 is configured to include the bottom portion of the recessed portion 24 that is open on one face of the substrate 2. The lower face of the diaphragm portion 20 is configured as a pressure reception face 25. In the present embodiment, the diaphragm portion 20 has a square plan-view shape as illustrated in FIG. 2.

In the substrate 2 of the present embodiment, the recessed portion 24 passes through the silicon layer 211, and the diaphragm portion 20 is configured of four layers of the silicon oxide layer 212, the silicon layer 213, the insulating film 22, and the insulating film 23. As described later, the silicon oxide layer 212 can be used as an etch stop layer when the recessed portion 24 is formed by etching in a process of manufacturing the physical quantity sensor 1. This can reduce variations in the thickness of the diaphragm portion 20 for each product manufactured.

The recessed portion 24 may not pass through the silicon layer 211. The diaphragm portion 20 may be configured of five layers of a thinned portion of the silicon layer 211, the silicon oxide layer 212, the silicon layer 213, the insulating film 22, and the insulating film 23.

### Piezoresistive Element (Functional Element)

Each of the plurality of piezoresistive elements 5 is formed on the cavity portion S side of the diaphragm portion 20 as illustrated in FIG. 1. The piezoresistive elements 5 are formed in the silicon layer 213 of the semiconductor substrate 21.

The plurality of piezoresistive elements 5 is configured of a plurality of piezoresistive elements 5a, 5b, 5c, and 5d that is arranged in the peripheral portion of the diaphragm portion 20 as illustrated in FIG. 2.

The piezoresistive element 5a, the piezoresistive element 5b, the piezoresistive element 5c, and the piezoresistive element 5d are respectively arranged in correspondence with the four edges of the diaphragm portion 20 that form a quadrangle in a plan view viewed from the thickness direction of the substrate 2 (hereinafter, simply referred to as “plan view”).

The piezoresistive element 5a extends along a direction perpendicular to the corresponding edge of the diaphragm portion 20. A pair of interconnects 214a is electrically connected to both of the end portions of the piezoresistive element 5a. Similarly, the piezoresistive element 5b extends along a direction perpendicular to the corresponding edge of the diaphragm portion 20. A pair of interconnects 214b is electrically connected to both of the end portions of the piezoresistive element 5b.

The piezoresistive element 5c, meanwhile, extends along a direction parallel to the corresponding edge of the diaphragm portion 20. A pair of interconnects 214c is electrically connected to both of the end portions of the piezoresistive element 5c. Similarly, the piezoresistive element 5d extends along a direction parallel to the corresponding edge of the diaphragm portion 20. A pair of interconnects 214d is electrically connected to both of the end portions of the piezoresistive element 5d.

Hereinafter, the interconnects 214a, 214b, 214c, and 214d may be collectively referred to as “interconnect 214”.

Such piezoresistive elements 5 and an interconnect 214 are configured of, for example, silicon (monocrystalline silicon) that is doped (through diffusion or implantation) with an impurity such as phosphorus or boron. The concentration of the dopant impurity in the interconnect 214 is higher than the concentration of the dopant impurity in the piezoresistive elements 5. The interconnect 214 may be configured of metal.

The plurality of piezoresistive elements 5, for example, is configured to have the same resistance value in a natural state.

The piezoresistive elements 5 described thus far constitute a bridge circuit (Wheatstone bridge circuit) through the interconnect 214 and the like. A drive circuit (not illustrated) that supplies drive voltage is connected to the bridge circuit. The bridge circuit outputs a signal (voltage) that corresponds to the resistance values of the piezoresistive elements 5.

### Laminated Structure

The laminated structure 6 is formed to define the cavity portion S between the laminated structure 6 and the substrate 2. The laminated structure 6 is arranged on the piezoresistive elements 5 side of the diaphragm portion 20 and defines (constitutes) the cavity portion S (inner space) along with the diaphragm portion 20 (or with the substrate 2).

The laminated structure 6 includes an interlayer insulating film 61, an interconnect layer 62, an interlayer insulating film 63, an interconnect layer 64, a surface protective film 65, and a seal layer 66. The interlayer insulating film 61 is formed on the substrate 2 to surround the piezoresistive elements 5 in a plan view. The interconnect layer 62 is formed on the interlayer insulating film 61. The interlayer insulating film 63 is formed on the interconnect layer 62 and the interlayer insulating film 61. The interconnect layer 64 is formed on the interlayer insulating film 63 and includes a cladding layer 641 that is provided with a plurality of pores 642 (open holes). The surface protective film 65 is formed on the interconnect layer 64 and the interlayer insulating film 63. The seal layer 66 is disposed on the cladding layer 641.

Each of the interlayer insulating films 61 and 63 is configured of, for example, a silicon oxide film. Each of the interconnect layer 62, the interconnect layer 64, and the seal layer 66 is configured of metal such as aluminum. The seal layer 66 seals the plurality of pores 642 that the cladding layer 641 includes. The surface protective film 65 is, for example, a laminated film of a silicon oxide film and a silicon nitride film.

In such a laminated structure 6, a structure that is configured of the interconnect layer 62 and the interconnect layer 64 excluding the cladding layer 641 constitutes “wall portion” that is arranged to surround the piezoresistive elements 5 on one face side of the substrate 2 in a plan view. A laminate that is configured of the cladding layer 641 and the seal layer 66 constitutes “ceiling portion” that is arranged on the opposite side of the wall portion from the substrate 2 and that constitutes the cavity portion S (inner space) along with the wall portion. The interconnect layer includes an inside beam portion 644 (substrate-side reinforcing portion) that is arranged on the substrate 2 side of the ceiling portion to reinforce the ceiling portion. The surface protective film 65 includes an outside beam portion 651 (outside reinforcing portion) that is arranged on the opposite side of the ceiling portion from the substrate 2 to reinforce the ceiling portion. The inside beam portion 644, the outside beam portion 651, and matters relevant to these will be described in detail later.

Such a laminated structure 6 can be formed by using a semiconductor manufacturing process such as a CMOS process. A semiconductor circuit may be fabricated on and above the silicon layer 213. The semiconductor circuit includes active elements such as an MOS transistor and besides includes other circuit elements such as a capacitor, an inductor, a resistor, a diode, and an interconnect (including the interconnects connected to the piezoresistive elements 5) that are formed if necessary.

The cavity portion S that is defined by the substrate 2 and the laminated structure 6 is an airtight space. The cavity portion S functions as a pressure reference chamber that provides a reference value of pressure that the physical quantity sensor 1 detects. In the present embodiment, the cavity portion S is in a vacuum state (pressure is less than or equal to 300 Pa). By making a vacuum state in the cavity portion S, the physical quantity sensor 1 can be used as “absolute pressure sensor” that detects pressure with a vacuum state as a reference, and thus the convenience of use of the physical quantity sensor 1 is improved.

The cavity portion S may not be in a vacuum state. The cavity portion S may be under atmospheric pressure, may be in a decreased pressure state where pressure is below atmospheric pressure, or may be in an increased pressure state where pressure is over atmospheric pressure. An inert gas such as a nitrogen gas and a noble gas may be sealed in the cavity portion S.

The configuration of the physical quantity sensor 1 is briefly described thus far.

In the physical quantity sensor 1 having such a configuration, a pressure P that the pressure reception face 25 of the diaphragm portion 20 receives deforms the diaphragm portion 20 as illustrated in FIG. 3A. This causes the piezoresistive elements 5a, 5b, 5c, and 5d to be strained as illustrated in FIG. 3B, and the resistance values of the piezoresistive elements 5a, 5b, 5c, and 5d are changed. Accordingly, the output of the bridge circuit configured of the piezoresistive elements 5a, 5b, 5c, and 5d is changed, and the magnitude of the pressure received on the pressure reception face 25 can be obtained on the basis of the output.

More specifically, the product of the resistance values of the piezoresistive elements 5a and 5b is the same as the product of the resistance values of the piezoresistive elements 5c and 5d in a natural state prior to the above-described deformation of the diaphragm portion 20, such as when the piezoresistive elements 5a, 5b, 5c, and 5d have the same resistance value. Thus, the output (potential difference) of the bridge circuit is zero.

Meanwhile, when the above-described deformation of the diaphragm portion 20 occurs, compressive strains and tensile strains occur respectively along the longitudinal direction and the widthwise direction of the piezoresistive elements 5a and 5b, and tensile strains and compressive strains occur respectively along the longitudinal direction and the widthwise direction of the piezoresistive elements 5c and 5d as illustrated in FIG. 3B. Therefore, when the above-described deformation of the diaphragm portion 20 occurs, either the resistance values of the piezoresistive elements 5a and 5b or the resistance values of the piezoresistive elements 5c and 5d are increased, and the other resistance values are decreased.

Such strain exerted on the piezoresistive elements 5a, 5b, 5c, and 5d causes a difference between the product of the resistance values of the piezoresistive elements 5a and 5b and the product of the resistance values of the piezoresistive elements 5c and 5d, and the output (potential difference) corresponding to the difference is output from the bridge circuit. The magnitude of the pressure (absolute pressure) received on the pressure reception face 25 can be obtained on the basis of the output from the bridge circuit.

The difference between the product of the resistance values of the piezoresistive elements 5a and 5b and the product of the resistance values of the piezoresistive elements 5c and 5d can be significantly changed because either the resistance values of the piezoresistive elements 5a and 5b or the resistance values of the piezoresistive elements 5c and 5d are increased while the other resistance values are decreased when the above-described deformation of the diaphragm portion 20 occurs. Accordingly, the output from the bridge circuit can be increased. As a result, pressure detection sensitivity can be increased.

As such, in the physical quantity sensor 1, the diaphragm portion 20 that the substrate 2 includes is disposed at a position where the diaphragm portion 20 overlaps with the cladding layer 641 and the seal layer 66 in a plan view. The diaphragm portion 20 is deformed in a flexural manner by the reception of pressure. Accordingly, it is possible to realize the physical quantity sensor 1 that can detect pressure. In addition, since the piezoresistive elements 5 arranged in the diaphragm portion 20 are sensor elements that output electrical signals from strain, pressure detection sensitivity can be improved.

### Inside Beam Portion and Outside Beam Portion

Hereinafter, the inside beam portion 644 and the outside beam portion 651 will be described in detail.

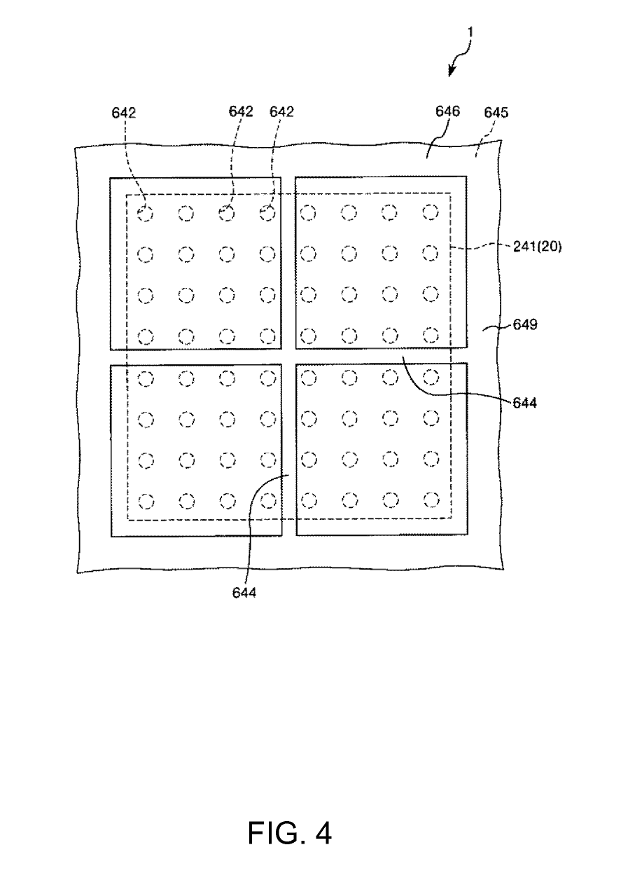

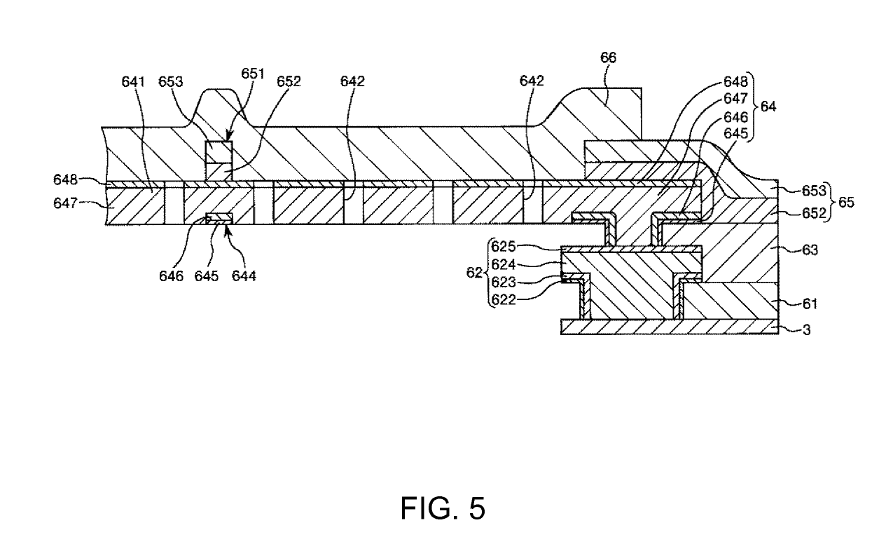

FIG. 4 is a plan view illustrating the arrangement of the inside beam portion (reinforcing portion) of the physical quantity sensor illustrated in FIG. 1. FIG. 5 is a partial enlarged sectional view of the physical quantity sensor illustrated in FIG. 1.

As described above, the interconnect layer 64 includes the inside beam portion 644 (substrate-side reinforcing portion) that is arranged on the substrate 2 side of the ceiling portion which is configured of a structure configured of the cladding layer 641 and the seal layer 66 (hereinafter, may be simply referred to as “ceiling portion”), and the surface protective film 65 includes the outside beam portion 651 (outside reinforcing portion) that is arranged on the opposite side of the ceiling portion from the substrate 2. Only a part of each of the inside beam portion 644 and the outside beam portion 651 overlaps with the ceiling portion in a plan view that is viewed in a direction in which the substrate 2 overlaps with the ceiling portion. Accordingly, it is possible to realize weight reduction. In addition, the inside beam portion 644 and the outside beam portion 651 have both of the end portions extending in a direction along the ceiling portion and, furthermore, have a part that extends in a straight line. Accordingly, since the expansion of the inside beam portion 644 and the outside beam portion 651 can be reduced, it is possible to realize the reduction of collapse of the ceiling portion. The entire parts of the inside beam portion 644 and the outside beam portion 651 between both ends thereof are more favorable if being formed in a straight line.

As such, the ceiling portion can be reinforced by the inside beam portion 644 and the outside beam portion 651. Particularly, since the inside beam portion 644 supports the ceiling portion on the substrate 2 side of the ceiling portion, that is, on the side onto which the ceiling portion collapses, the ceiling portion can be efficiently reinforced by the inside beam portion 644. Thus, it is possible to realize the compatibility of the strength and weight reduction of a structure that includes the ceiling portion and the configuration which reinforces the ceiling portion.

The inside beam portion 644 includes a material of which the thermal expansion rate is smaller than that of the ceiling portion. Thus, it is possible to reduce the thermal expansion of the ceiling portion with the inside beam portion 644 and also to reduce the deformation (collapse) of the ceiling portion due to thermal expansion. Accordingly, it is possible to reduce the collapse of the ceiling portion and in turn, to increase the reliability of the physical quantity sensor 1.

The cladding layer 641 has a rectangular shape in a plan view. The interconnect layer 64 includes a ring-shaped frame portion 649 that is formed along the periphery of the plan-view shape of the cladding layer 641. The inside beam portion 644, in a plan view, has a cross shape extending in directions orthogonal with respect to each other, and each end portion thereof is connected to each edge of the inner periphery of the frame portion 649. That is, the inside beam portion 644 is configured of a first beam portion and a second beam portion: The first beam portion connects two facing edges of the four edges that constitute the inner periphery of the frame portion 649 which has a rectangular shape in a plan view, and the second beam portion connects the other two facing edges while intersecting and being connected to the first beam portion. The frame portion 649 that is connected to both ends of the inside beam portion 644 includes the same material as the inside beam portion 644. Accordingly, it is possible to integrally form the inside beam portion 644 and the frame portion 649 together at the same time into one same layer. Thus, the inside beam portion 644 can have excellent mechanical strength. In addition, the frame portion 649 can be used in other situations such as an anti-reflective film in the case of exposing a photoresist to light. In the present embodiment, each of the first beam portion and the second beam portion constituting the inside beam portion 644 has a constant width.

Although not illustrated, the outside beam portion 651 that is provided in quantities of two has a cross shape extending in directions orthogonal with respect to each other and is disposed in correspondence with the inside beam portion 644 that is provided in quantities of two such that the outside beam portion 651 overlaps with the inside beam portion 644 in a plan view.

In the present embodiment, as illustrated in FIG. 5, the interconnect layer 62 is configured to include a Ti layer 622 configured of titanium (Ti), a TiN layer 623 configured of titanium nitride (TiN), an Al layer 624 configured of aluminum (Al), and a TiN layer 625 configured of titanium nitride (TiN), in which these layers are laminated in this order.

Similarly, the interconnect layer 64 is configured to include a Ti layer 645 configured of titanium (Ti), a TiN layer 646 configured of titanium nitride (TiN), an Al layer 647 configured of aluminum (Al), and a TiN layer 648 configured of titanium nitride (TiN), in which these layers are laminated in this order.

The inside beam portion 644 is configured of parts of the Ti layer 645 and the TiN layer 646. The TiN layer 646 is apart of an anti-reflective film that is used in an exposure process of photolithography and is formed by using the anti-reflective film.

As such, since the ceiling portion includes aluminum and since the inside beam portion 644 includes titanium or a titanium compound, it is possible to form the ceiling portion having excellent air tightness comparatively simply and accurately. In addition, the inside beam portion 644 can be formed by using an anti-reflective film that is used in an exposure process of photolithography. In addition, titanium or titanium compounds have a smaller thermal expansion rate than aluminum.

Since the TiN layer 648 is arranged between the Al layer 647 and the seal layer 66, it is possible to dispose the pores 642 that are used as a release hole in the Al layer 647 and to close the pores 642 with the seal layer 66. In addition, the TiN layer 648 can be formed by using a film (for example, an anti-reflective film) that is disposed on the Al layer 647 during manufacturing. It is also possible to reduce the thermal expansion of the Al layer 647 and the seal layer 66 with the TiN layer 648. Here, the Al layer 647 is “first layer”, and the seal layer 66 is “second layer” that is arranged on the opposite side of the first layer from the substrate 2 and that includes the same material as the first layer. The TiN layer 648 is “intermediate layer” that is arranged between the first layer and the second layer and that includes a material of which the thermal expansion rate is smaller than those of the first layer and the second layer.

The outside beam portion 651 is arranged between the TiN layer 648 and the seal layer 66 at a position where the outside beam portion 651 overlaps with at least a part of the inside beam portion 644 in a plan view. Accordingly, the ceiling portion can also be reinforced by the outside beam portion 651. In addition, since the outside beam portion 651 overlaps with the inside beam portion 644 in a plan view, it is possible to arrange the pores 642 that are used as a release hole in the ceiling portion (cladding layer 641) with comparatively high density of arrangement without separating working of the inside beam portion 644 and the outside beam portion 651.

The pores 642 does not overlap with the inside beam portion 644 and the outside beam portion 651 in a plan view and are arranged to be distributed as widely as possible. Particularly, in a plan view, the plurality of pores 642 is arranged such that the pores 642 even exist at positions close to the corner portions of the cladding layer 641. Accordingly, it is possible to efficiently perform etching through the pores 642 in the manufacturing process described later.

### Method for Manufacturing Physical Quantity Sensor

Next, a method for manufacturing the physical quantity sensor 1 will be briefly described.

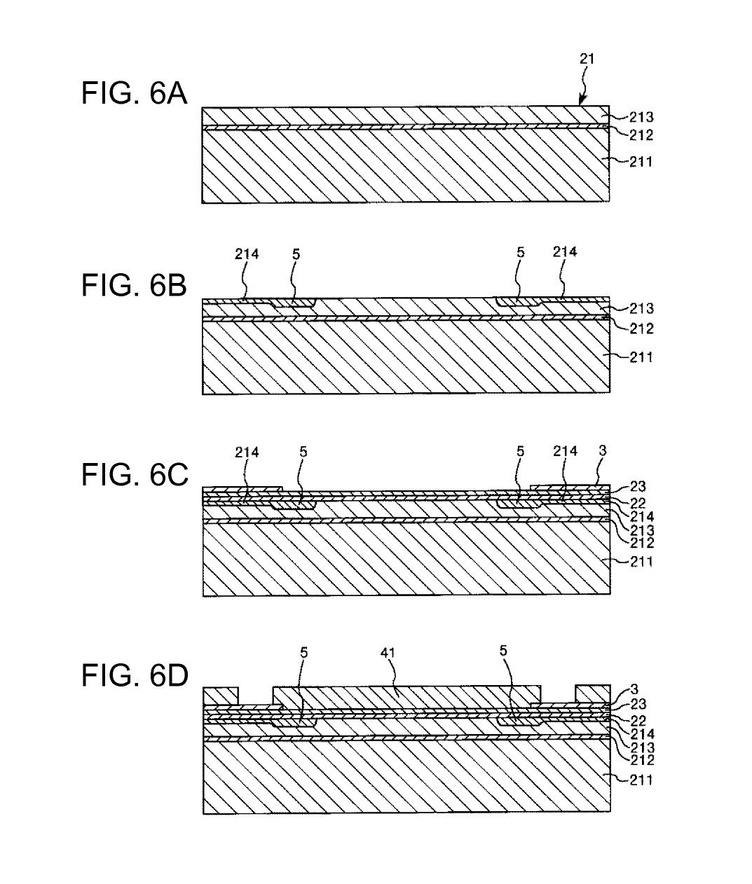

FIG. 6A to FIG. 8C are diagrams illustrating the process of manufacturing the physical quantity sensor 1 illustrated in FIG. 1. Hereinafter, the method for manufacturing the physical quantity sensor 1 will be described on the basis of these drawings.

### Element Forming Process

First, the semiconductor substrate 21 that is an SOI substrate is prepared as illustrated in FIG. 6A.

The plurality of piezoresistive elements 5 and the interconnect 214 are formed as illustrated in FIG. 6B by doping (through ion implantation) the silicon layer 213 of the semiconductor substrate 21 with an impurity such as phosphorus (n-type) or boron (p-type).

The concentration of ions implanted into the piezoresistive elements 5 is approximately 1×10¹⁴ atoms/cm² in the case of, for example, implanting boron ions at an energy of +80 keV. The concentration of ions implanted into the interconnect 214 is set to be greater than that of the piezoresistive elements 5. The concentration of ions implanted into the interconnect 214 is approximately 5×10¹⁵ atoms/cm² in the case of, for example, implanting boron ions at an energy of 10 keV. After ions are implanted as described above, for example, annealing is performed at approximately 1000° C. for approximately 20 minutes.

### Insulating Film and the Like Forming Process

Next, the insulating film 22, the insulating film 23, and the intermediate layer 3 are formed in this order on the silicon layer 213 as illustrated in FIG. 6C.

Each of the insulating films 22 and 23 can be formed by, for example, sputtering or CVD. The intermediate layer 3 can be formed by, for example, depositing polycrystalline silicon through sputtering, CVD, or the like, doping (through ion implantation) the film with an impurity such as phosphorus or boron if necessary, and patterning the film through etching.

### Interlayer Insulating Film and Interconnect Layer Forming Process

Next, a sacrificial layer 41 is formed on the insulating film 23 as illustrated in FIG. 6D.

A part of the sacrificial layer 41 is removed by a cavity portion forming process described later, and the remaining part thereof is configured as the interlayer insulating film 61. The sacrificial layer 41 includes through holes so that the interconnect layer 62 can pass therethrough. The sacrificial layer 41 is formed by forming a silicon oxide film through sputtering, CVD, or the like and by patterning the silicon oxide film through etching.

The thickness of the sacrificial layer 41, although not particularly limited, is for example, approximately greater than or equal to 1500 nm and less than or equal to 5000 nm.

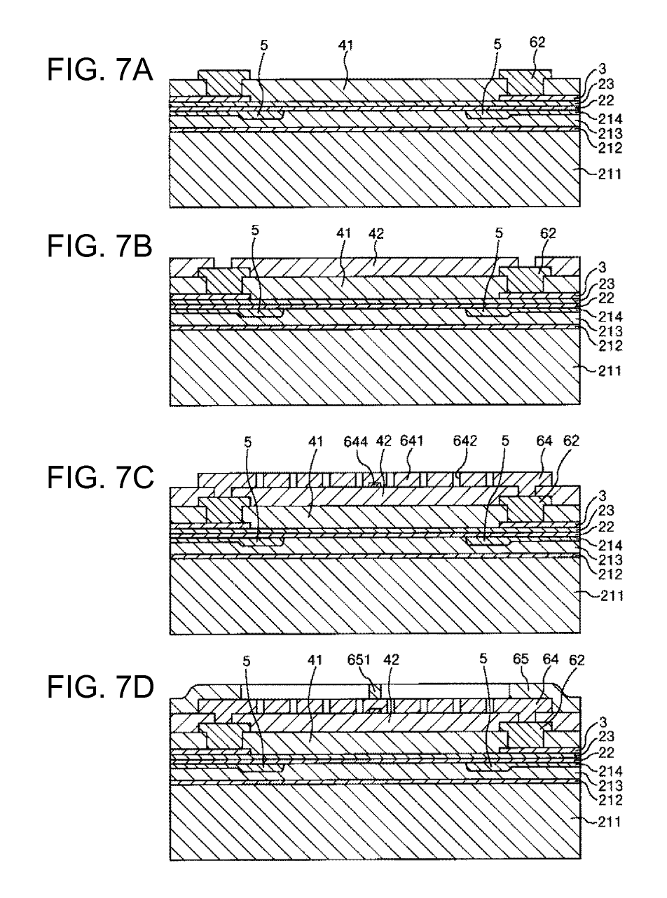

Next, the interconnect layer 62 is formed to fill the through holes formed in the sacrificial layer 41 as illustrated in FIG. 7A.

The interconnect layer 62 can be formed by, for example, forming a uniform conductive film through sputtering, CVD, or the like and by patterning the conductive film. Although illustration is not provided, when the interconnect layer 62 that includes the Ti layer 622, the TiN layer 623, the Al layer 624, and the TiN layer 625 is formed, the Ti layer 622 and the TiN layer 623 are formed by uniformly forming a Ti layer and a TiN layer in this order and by patterning these layers, and afterward, the Al layer 624 and the TiN layer 625 are formed by uniformly forming an Al layer and a TiN layer in this order and by patterning these layers. The TiN layer 623 has a function of increasing the wettability of Al so as to make the ability of Al to fill the through holes of the sacrificial layer 41 favorable, and the Ti layer 622 has a function of increasing adhesion between the TiN layer 623 and the sacrificial layer 41. The TiN layer that is uniformly formed on the Al layer functions as an anti-reflective film that prevents the reflection of light used in an exposure process of photolithography when the Al layer 624 and the TiN layer 625 are formed by patterning.

The thickness of the interconnect layer 62, although not particularly limited, is for example, approximately greater than or equal to 300 nm and less than or equal to 900 nm.

Next, a sacrificial layer 42 is formed on the sacrificial layer 41 and the interconnect layer 62 as illustrated in FIG. 7B.

Apart of the sacrificial layer 42 is removed by the cavity portion forming process described later, and the remaining part thereof is configured as the interlayer insulating film 63. The sacrificial layer 42 includes through holes so that the interconnect layer 64 can pass therethrough. The sacrificial layer 42, in the same manner as the above formation of the sacrificial layer 41, is formed by forming a silicon oxide film through sputtering, CVD, or the like and by patterning the silicon oxide film through etching.

The thickness of the sacrificial layer 42, although not particularly limited, is for example, approximately greater than or equal to 1500 nm and less than or equal to 5000 nm.

Next, the interconnect layer 64 is formed to fill the through holes formed in the sacrificial layer 42 as illustrated in FIG. 7C.

The interconnect layer 64 can be formed by, for example, forming a uniform conductive film through sputtering, CVD, or the like and by patterning the conductive film. Although illustration is not provided, when the interconnect layer 64 that includes the Ti layer 645, the TiN layer 646, the Al layer 647, and the TiN layer 648 is formed, the Ti layer 645 and the TiN layer 646 are formed by uniformly forming a Ti layer and a TiN layer in this order and by patterning these layers, and afterward, the Al layer 647 and the TiN layer 648 are formed by uniformly forming an Al layer and a TiN layer in this order and by patterning these layers. The TiN layer 646 has a function of increasing the wettability of Al so as to make the ability of Al to fill the through holes of the sacrificial layer 42 favorable, and the Ti layer 645 has a function of increasing adhesion between the TiN layer 646 and the sacrificial layer 42. The TiN layer that is uniformly formed on the Al layer functions as an anti-reflective film that prevents the reflection of light used in an exposure process of photolithography when the Al layer 647 and the TiN layer 648 are formed by patterning.

The thickness of the interconnect layer 64, although not particularly limited, is for example, approximately greater than or equal to 300 nm and less than or equal to 900 nm.

The sacrificial layers 41 and 42 and the interconnect layers 62 and 64 are formed as described thus far. A laminated structure configured of the sacrificial layers 41 and 42 and the interconnect layers 62 and 64 is formed by using a typical CMOS process, and the number of layers laminated is appropriately set according to the necessity thereof. That is, more sacrificial layers and interconnect layers may be laminated if necessary.

Afterward, the surface protective film 65 is formed by sputtering, CVD, or the like as illustrated in FIG. 7D. Accordingly, the parts of the sacrificial layers 41 and 42 configured as the interlayer insulating films 61 and 63 can be protected when etching is performed in the cavity portion forming process described later.

Although illustration is not provided, when the surface protective film 65 that includes an SiO₂ layer 652 and an SiN layer 653 is formed, the SiO₂ layer 652 and the SiN layer 653 are formed by uniformly forming an SiO₂ layer and an SiN layer in this order and by patterning these layers.

The configuration of the surface protective film 65 is not limited to the one described above. Examples of a material constituting the surface protective film 65 include materials that have tolerance such as a silicon oxide film, a silicon nitride film, a polyimide film, and an epoxy resin film so as to protect elements from moisture, dust, scratches, and the like. Particularly, a silicon nitride film is preferred.

The thickness of the surface protective film 65, although not particularly limited, is for example, approximately greater than or equal to 500 nm and less than or equal to 2000 nm.

### Cavity Portion Forming Process

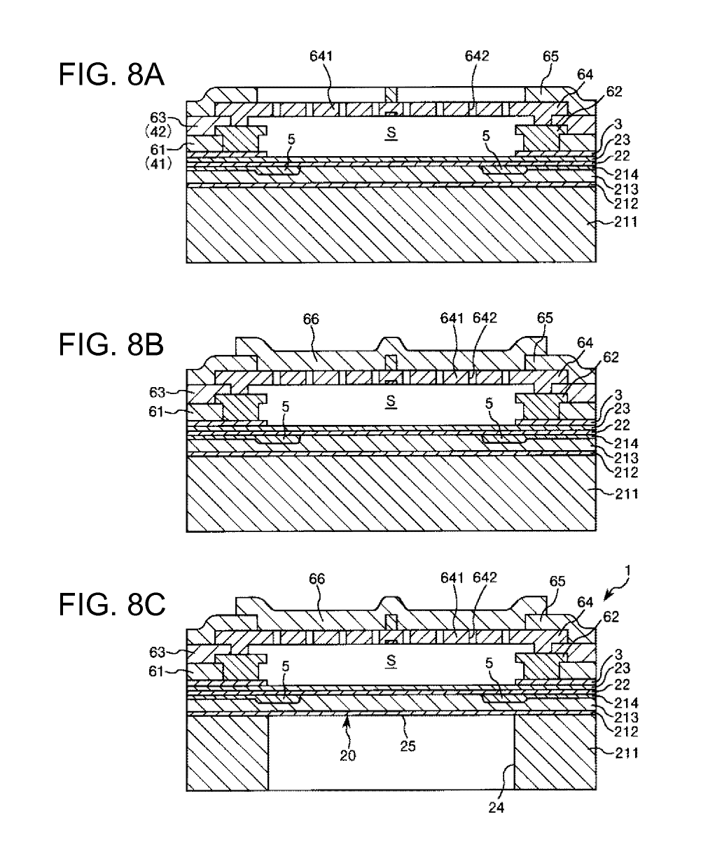

Next, the cavity portion S (cavity) is formed between the insulating film 23 and the cladding layer 641 as illustrated in FIG. 8A by removing parts of the sacrificial layers 41 and 42. Accordingly, the interlayer insulating films 61 and 63 are formed.

The cavity portion S is formed by removing parts of the sacrificial layers 41 and 42 by etching that is performed through the plurality of pores 642 formed in the cladding layer 641. When wet etching is used as the etching, etching liquid such as hydrofluoric acid or buffered hydrofluoric acid is supplied from the plurality of pores 642. When dry etching is used, etching gas such as hydrofluoric acid gas is supplied from the plurality of pores 642. The insulating film 23 functions as an etch stop layer when such etching is performed. In addition, since the insulating film 23 has tolerance to etching liquid, the insulating film 23 has a function of protecting components on the lower side of the insulating film 23 (for example, the insulating film 22, the piezoresistive elements 5, and the interconnect 214) from etching liquid.

### Sealing Process

Next, the seal layer 66 that is configured of, for example, a silicon oxide film, a silicon nitride film, or a film made of metal such as Al, Cu, W, Ti, or TiN is formed on the cladding layer 641 by sputtering, CVD, or the like to seal each of the pores 642 as illustrated in FIG. 8B. Accordingly, the cavity portion S is sealed by the seal layer 66, and the laminated structure 6 is obtained.

The thickness of the seal layer 66, although not particularly limited, is for example, approximately greater than or equal to 1000 nm and less than or equal to 5000 nm.

### Diaphragm Forming Process

Next, the recessed portion 24 is formed by grinding the lower face of the silicon layer 211 if necessary and by removing (working) apart of the lower face of the silicon layer 211 through etching as illustrated in FIG. 8C. Accordingly, the diaphragm portion 20 that faces the cladding layer 641 through the cavity portion S is formed.

The silicon oxide layer 212 functions as an etch stop layer when a part of the lower face of the silicon layer 211 is removed. Accordingly, the thickness of the diaphragm portion 20 can be accurately defined.

Either dry etching or wet etching or the like may be used as a method for removing a part of the lower face of the silicon layer 211.

According to the processes described thus far, it is possible to manufacture the physical quantity sensor 1.

### Second Embodiment

Next, a second embodiment of the invention will be described.

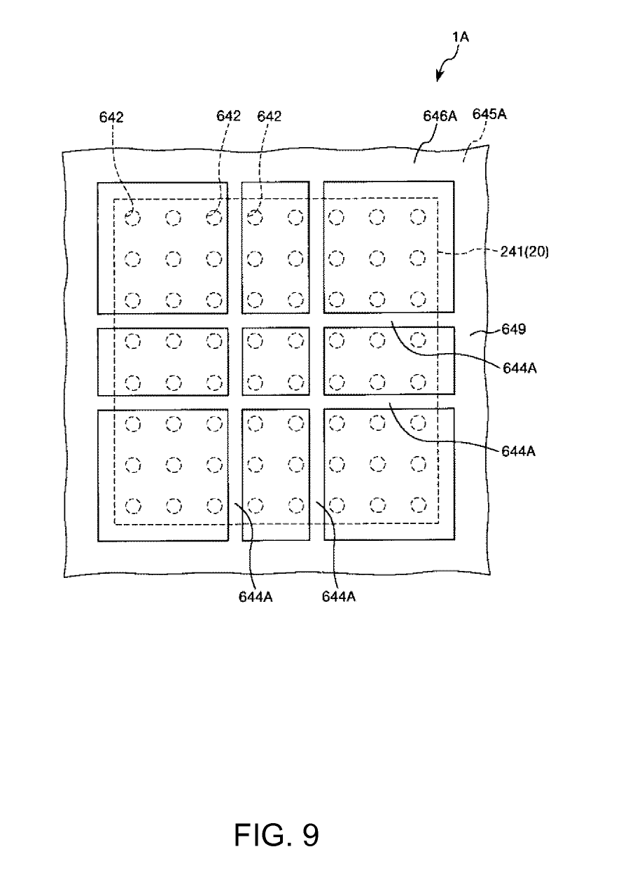

FIG. 9 is a plan view illustrating the arrangement of an inside beam portion (reinforcing portion) of a physical quantity sensor that is in accordance with the second embodiment of the invention.

Hereinafter, while the second embodiment of the invention will be described, differences between the second embodiment and the above embodiment will be mainly described, and the same matter will not be described.

The present embodiment is the same as the first embodiment except that the shape of the inside beam portion is different in a plan view.

A physical quantity sensor 1A illustrated in FIG. 9 includes an inside beam portion 644A that is configured of a Ti layer 645A and a TiN layer 646A.

The inside beam portion 644A is configured of two first beam portions and two second beam portions. The first beam portions connect two facing edges of the four edges that constitute the inner periphery of the frame portion 649 which has a rectangular shape in a plan view, and the second beam portions connects the other two facing edges while intersecting and being connected to each of the first beam portions. As such, since the inside beam portion 644A is configured of four beam portions, the reinforcing effect of the inside beam portion 644A can be excellent.

According to such a physical quantity sensor 1A, it is possible to reduce the collapse of the ceiling portion and in turn, to increase reliability.

### Third Embodiment

Next, a third embodiment of the invention will be described.

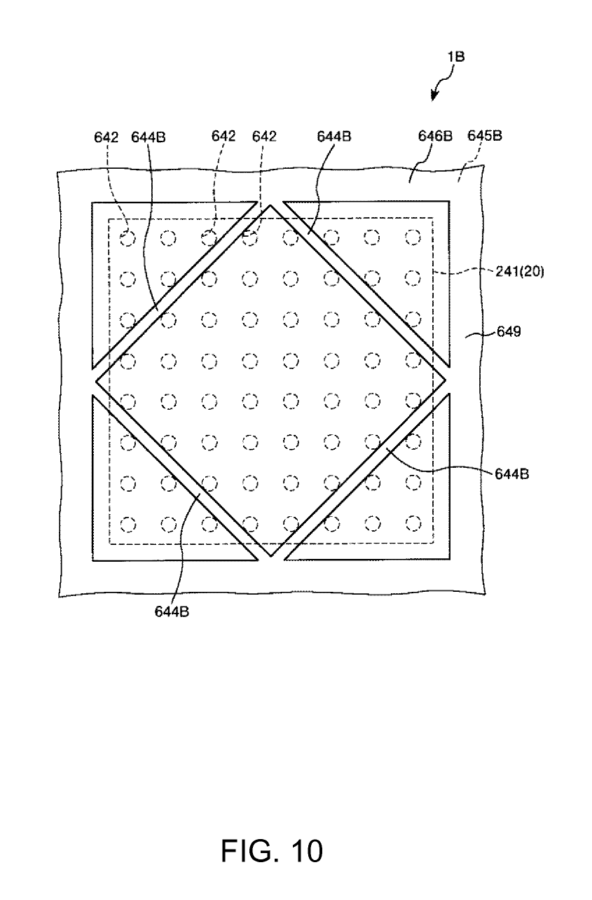

FIG. 10 is a plan view illustrating the arrangement of an inside beam portion (reinforcing portion) of an electronic device (physical quantity sensor) that is in accordance with the third embodiment of the invention.

Hereinafter, while the third embodiment of the invention will be described, differences between the third embodiment and the above embodiments will be mainly described, and the same matter will not be described.

The present embodiment is the same as the first embodiment except that the shape of the inside beam portion is different in a plan view.

A physical quantity sensor 1B illustrated in FIG. 10 includes an inside beam portion 644B that is configured of a Ti layer 645B and a TiN layer 646B.

The inside beam portion 644B is configured of four beam portions that connect two adjacent edges of the four edges constituting the inner periphery of the frame portion 649 which has a rectangular shape in a plan view.

According to such a physical quantity sensor 1B, it is possible to reduce the collapse of the ceiling portion and in turn, to increase reliability.

### Fourth Embodiment

Next, a fourth embodiment of the invention will be described.

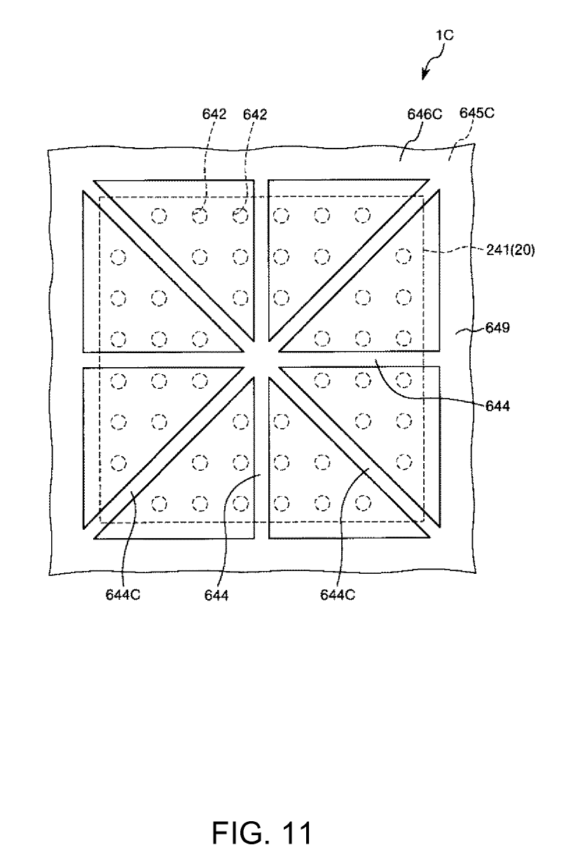

FIG. 11 is a plan view illustrating the arrangement of an inside beam portion (reinforcing portion) of an electronic device (physical quantity sensor) that is in accordance with the fourth embodiment of the invention.

Hereinafter, while the fourth embodiment of the invention will be described, differences between the fourth embodiment and the above embodiments will be mainly described, and the same matter will not be described.

The present embodiment is the same as the first embodiment except that the shape of the inside beam portion is different in a plan view.

A physical quantity sensor 1C illustrated in FIG. 11 includes inside beam portions 644 and 644C that are configured of a Ti layer 645C and a TiN layer 646C.

The inside beam portion 644C is configured of a first beam portion and a second beam portion. The first beam portion connects two facing corner portions of the four corner portions of the inner periphery of the frame portion 649 which has a rectangular shape in a plan view, and the second beam portion connects the other two facing corner portions while intersecting and being connected to the first beam portion. The inside beam portion 644C intersects and is connected to the inside beam portion 644. By adding such an inside beam portion 644C, it is possible to effectively prevent the collapse of the ceiling portion along with the reinforcing effect of the inside beam portion 644.

According to such a physical quantity sensor 1C, it is possible to reduce the collapse of the ceiling portion and in turn, to increase reliability.

### Fifth Embodiment

Next, a fifth embodiment of the invention will be described.

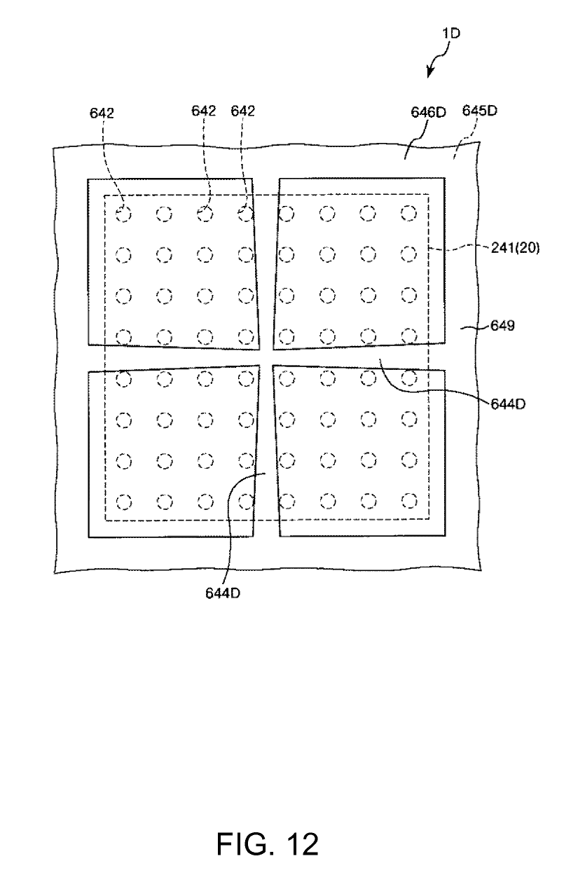

FIG. 12 is a plan view illustrating the arrangement of an inside beam portion (reinforcing portion) of an electronic device (physical quantity sensor) that is in accordance with the fifth embodiment of the invention.

Hereinafter, while the fifth embodiment of the invention will be described, differences between the fifth embodiment and the above embodiments will be mainly described, and the same matter will not be described.

The present embodiment is the same as the first embodiment except that the shape of the inside beam portion is different in a plan view.

A physical quantity sensor 1D illustrated in FIG. 12 includes an inside beam portion 644D that is configured of a Ti layer 645D and a TiN layer 646D.

The inside beam portion 644D is configured of a first beam portion and a second beam portion. The first beam portion connects two facing edges of the four edges of the inner periphery of the frame portion 649 which has a rectangular shape in a plan view, and the second beam portion connects the other two facing edges while intersecting and being connected to the first beam portion.

In the present embodiment, each of the first beam portion and the second beam portion constituting the inside beam portion 644D is configured to have a width that gradually decreases from the outside (outer periphery side) toward the inside (central portion side) in a plan view. Accordingly, it is possible to reduce an increase in the mass of the inside beam portion 644D and to increase the reinforcing effect of the inside beam portion 644D.

According to such a physical quantity sensor 1D, it is possible to reduce the collapse of the ceiling portion and in turn, to increase reliability.

### Sixth Embodiment

Next, a sixth embodiment of the invention will be described.

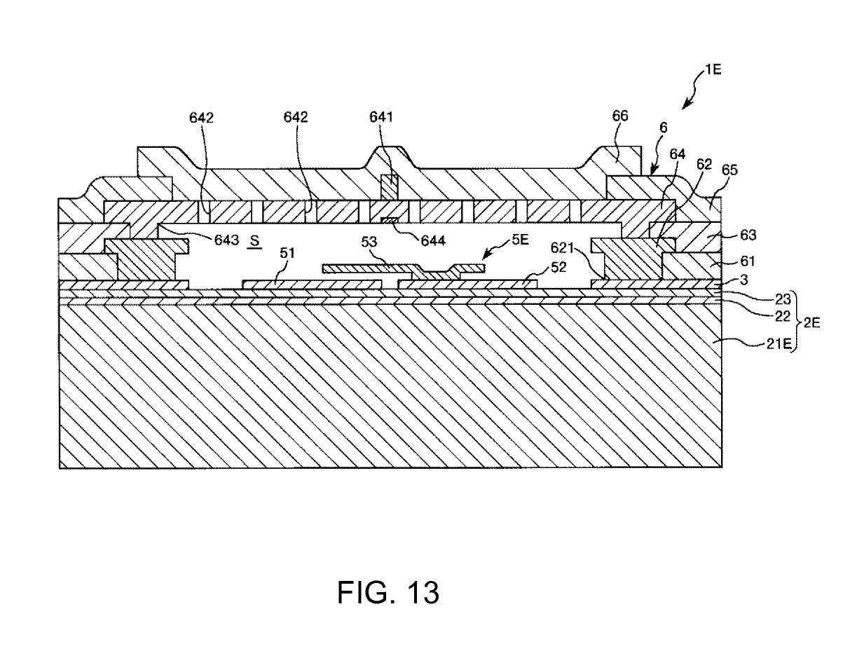

FIG. 13 is a sectional view illustrating an electronic device (vibrator) that is in accordance with the sixth embodiment of the invention.

Hereinafter, while the sixth embodiment of the invention will be described, differences between the sixth embodiment and the above embodiments will be mainly described, and the same matter will not be described.

The present embodiment is the same as the first embodiment except that the electronic device according to the invention is applied to a vibrator.

An electronic device 1E illustrated in FIG. 13 is configured in the same manner as the physical quantity sensor 1 of the first embodiment except that the electronic device 1E is provided with a substrate 2E and a resonator 5E (functional element) instead of the substrate 2 and the piezoresistive elements 5. That is, the electronic device 1E is provided with the substrate 2E, the resonator 5E, the laminated structure 6, and the intermediate layer 3: The resonator 5E that is a functional element is arranged on the substrate 2E, the laminated structure 6 forms the cavity portion S (inner space) along with the substrate 2E, and the intermediate layer 3 is arranged between the substrate 2E and the laminated structure 6.

The substrate 2E includes a semiconductor substrate 21E, the insulating film 22, and the insulating film 23. The insulating film 22 is disposed on one face of the semiconductor substrate 21E. The insulating film 23 is disposed on the opposite face of the insulating film 22 from the semiconductor substrate 21E.

The semiconductor substrate 21E is flat and is, for example, a monocrystalline silicon substrate. An SOI substrate may also be used as the semiconductor substrate 21E.

The resonator 5E includes a pair of lower electrodes and 52 and an upper electrode 53. The pair of lower electrodes 51 and 52 is arranged on the insulating film 23 of the substrate 2E. The upper electrode 53 is supported by the lower electrode 52.

The lower electrodes 51 and 52 have a plate shape or a sheet shape along the substrate 2E and are arranged at an interval. Although illustration is not provided, each of the lower electrodes 51 and 52 is electrically connected to an interconnect that the intermediate layer 3 includes. The lower electrode 51 constitutes “fixed electrode”. The lower electrode 52 may not be provided. In this case, the upper electrode 53 is favorable if being directly fixed to the insulating film 23.

The upper electrode 53 includes a movable portion, a fixed portion, and a connecting portion. The movable portion has a plate shape or a sheet shape and faces the lower electrode 51 at an interval. The fixed portion is fixed to the lower electrode 52. The connecting portion connects the movable portion and the fixed portion. The upper electrode 53 is electrically connected to the lower electrode 52. The upper electrode 53 constitutes “movable electrode”.

Such lower electrodes 51 and 52 and an upper electrode 53 are configured by doping (through diffusion or implantation) monocrystalline silicon, polycrystalline silicon (polysilicon), or amorphous silicon with an impurity such as phosphorus or boron and have conductivity. The lower electrodes 51 and 52 can be formed together with the intermediate layer 3 at the same time.

In such an electronic device 1E, by applying periodically changing voltage between the lower electrode 51 and the upper electrode 53, the movable portion of the upper electrode 53 vibrates in a flexural manner while changing the position thereof alternately in a direction approaching the lower electrode 51 and in a direction receding from the lower electrode 51. As such, the electronic device 1E can be used as an electrostatically driven vibrator that vibrates the movable portion of the upper electrode 53 by generating a periodically changing electric field between the lower electrode 51 and the movable portion of the upper electrode 53.

Such an electronic device 1E in combination with, for example, an oscillator circuit (drive circuit) can be used as an oscillator that obtains signals having a predetermined frequency. The oscillator circuit can be disposed as a semiconductor circuit on the substrate 2E.

According to such an electronic device 1E, it is possible to reduce the collapse of the ceiling portion and in turn, to increase reliability.

### 2. Pressure Sensor

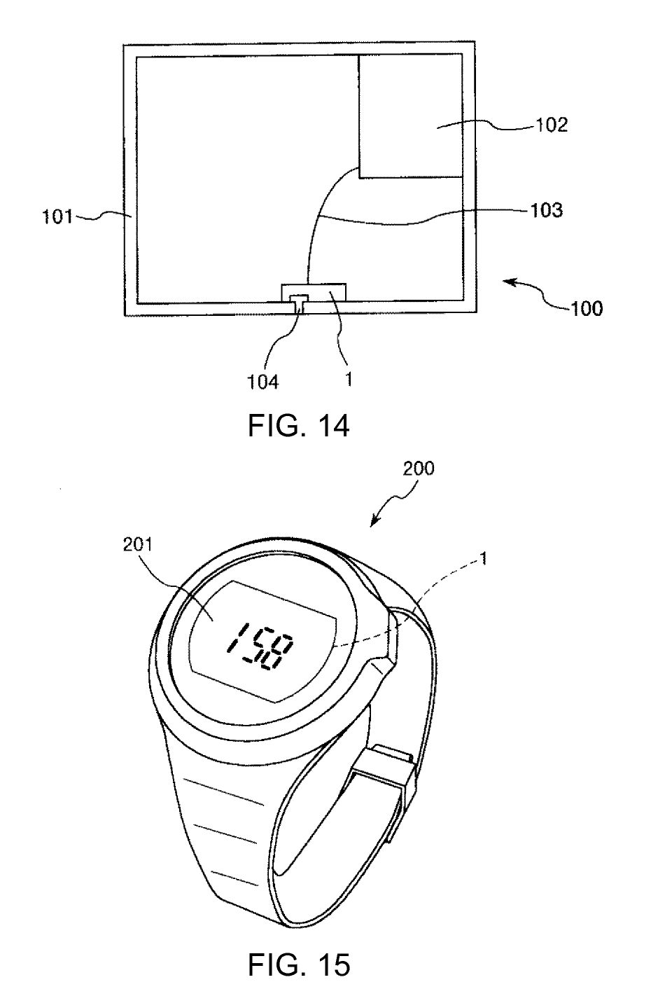

Next, a pressure sensor that is provided with the physical quantity sensor according to the invention (pressure sensor according to the invention) will be described. FIG. 14 is a sectional view illustrating an example of the pressure sensor according to the invention.

A pressure sensor 100 according to the invention, as illustrated in FIG. 14, is provided with the physical quantity sensor 1, a casing 101, and an operation unit 102. The casing 101 accommodates the physical quantity sensor 1. The operation unit 102 performs an operation of obtaining pressure data from a signal that is obtained from the physical quantity sensor 1. The physical quantity sensor 1 is electrically connected to the operation unit 102 through an interconnect 103.

The physical quantity sensor 1 is fixed inside the casing 101 by an unillustrated fixing unit. The casing 101 includes a through hole 104 so that the diaphragm portion 20 of the physical quantity sensor 1, for example, can communicate with the atmosphere (outside of the casing 101).

According to such a pressure sensor 100, the diaphragm portion 20 receives pressure through the through hole 104. A signal corresponding to the received pressure is transmitted to the operation unit through the interconnect 103 so as to perform the operation of obtaining pressure data. The pressure data obtained from the operation can be displayed via an unillustrated display unit (for example, a monitor of a personal computer).

### 3. Altimeter

Next, an example of an altimeter that is provided with the physical quantity sensor according to the invention (altimeter according to the invention) will be described. FIG. 15 is a perspective view illustrating an example of the altimeter according to the invention.

An altimeter 200 can be worn on a wrist as a wristwatch. The physical quantity sensor 1 (pressure sensor 100) is mounted in the altimeter 200. A display unit 201 can display the altitude of the current location above sea level, the atmospheric pressure of the current location, or the like.

The display unit 201 can display various information such as the current time, the heart rate of a user, and weather.

### 4. Electronic Apparatus

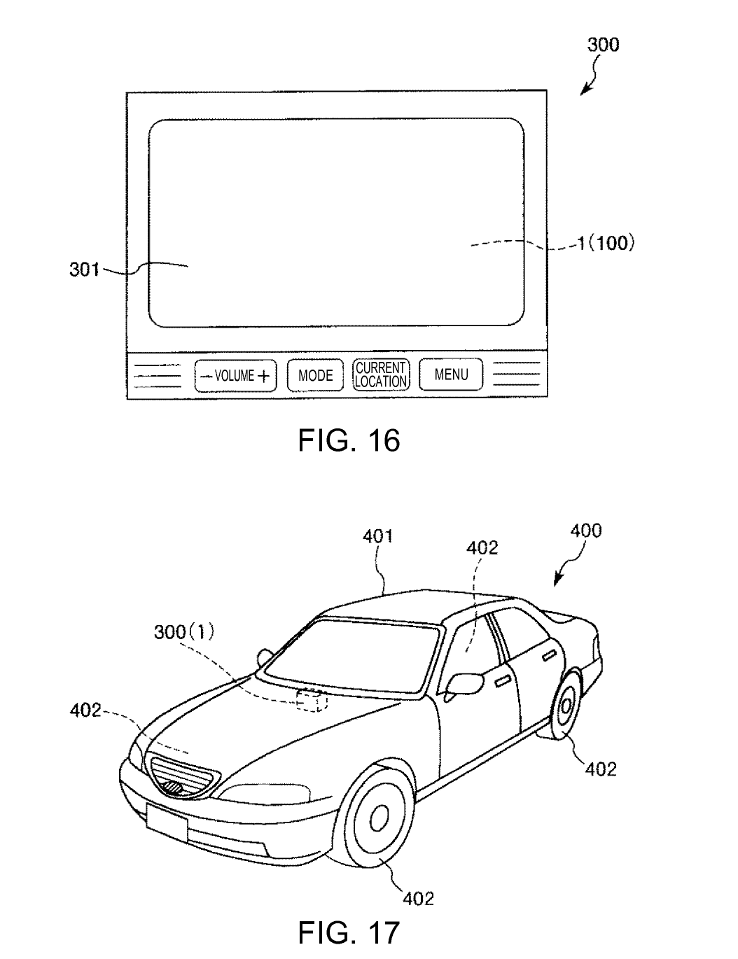

Next, a navigation system to which an electronic apparatus provided with the physical quantity sensor according to the invention is applied will be described. FIG. 16 is a front view illustrating an example of the electronic apparatus according to the invention.

A navigation system 300 is provided with unillustrated map information, a positional information obtaining unit, a self-contained navigation unit, the physical quantity sensor 1, and a display unit 301. The positional information obtaining unit obtains positional information from a global positioning system (GPS). The self-contained navigation unit is configured of a gyro sensor, an acceleration sensor, and vehicle speed data. The display unit 301 displays predetermined positional information or course information.

According to the navigation system, altitude information can be obtained in addition to the obtained positional information. A navigation system that does not have altitude information cannot determine whether a vehicle traverses a typical road or an elevated road when, for example, the vehicle traverses an elevated road that is represented at substantially the same position as a typical road in the positional information. Thus, such a navigation system provides information of the typical road as prioritized information to the user. The navigation system 300 according to the present embodiment can obtain the altitude information with the physical quantity sensor 1 and thus can provide the user with navigation information about the state of the vehicle traversing an elevated road by detecting an altitude change that is caused by the vehicle entering an elevated road from a typical road.

The display unit 301 has a configuration that can be reduced and thinned in size, such as a liquid crystal panel display and an organic electroluminescence (EL) display.

The electronic apparatus that is provided with the physical quantity sensor according to the invention is not limited to the above example and can be applied to, for example, a personal computer, a cellular phone, a medical apparatus (for example, an electronic thermometer, a sphygmomanometer, a blood glucose meter, an electrocardiograph, an ultrasonic diagnostic apparatus, and an electronic endoscope), various measuring apparatuses, meters (for example, meters in a vehicle, an airplane, and a ship), and a flight simulator.

### 5. Moving Object

Next, a moving object to which the physical quantity sensor according to the invention is applied (moving object according to the invention) will be described. FIG. 17 is a perspective view illustrating an example of the moving object according to the invention.

A moving object 400, as illustrated in FIG. 17, includes a vehicle body 401 and four wheels 402 and is configured to rotate the wheels 402 with an unillustrated drive source (engine) that is disposed in the vehicle body 401. The navigation system 300 (physical quantity sensor 1) is incorporated into such a moving object 400.

While the electronic device, the physical quantity sensor, the pressure sensor, the vibrator, the altimeter, the electronic apparatus, and the moving object according to the invention are described thus far on the basis of each illustrated embodiment, the invention is not limited to those embodiments. Configurations of each unit can be substituted by an arbitrary configuration that has the same function. In addition, other arbitrary constituents may be added.

While the above embodiments are described in the case where the number of piezoresistive elements (functional elements) disposed in one diaphragm portion is four, the invention is not limited to this. For example, the number of piezoresistive elements may be greater than or equal to one and less than or equal to three or may be greater than or equal to five. In addition, the arrangement, shape, and the like of the piezoresistive elements are not limited to the above embodiments. For example, the piezoresistive elements may also be arranged in the central portion of the diaphragm portion in the above embodiments.

While the above embodiments are described in the case where the piezoresistive elements are used as a sensor element that detects bending of the diaphragm portion, the invention is not limited to this. For example, such an element may be a resonator.

The invention can be applied to various electronic devices without being limited to the above embodiments, provided that the electronic device according to the invention is an electronic device in which a wall portion and a ceiling portion are formed on a substrate by using a semiconductor manufacturing process and in which an inner space is formed by the substrate, the wall portion, and the ceiling portion.

What is claimed is:

1. An electronic device comprising:
a substrate;
a functional element that is arranged on one face side of the substrate;
a wall portion that is arranged to surround the functional element on the one face side of the substrate in a plan view of the substrate;
a ceiling portion that is arranged on the opposite side of the wall portion from the substrate and constitutes an inner space with the wall portion; and
an inside beam portion that is arranged on the substrate side of the ceiling portion, has a part that overlaps with the ceiling portion in a plan view, and includes a material of which the thermal expansion rate is smaller than the thermal expansion rate of the ceiling portion.

2. The electronic device according to claim 1, further comprising:
a frame portion that is connected to an end portion of the inside beam portion and includes the same material as the inside beam portion.

3. The electronic device according to claim 1,
wherein the ceiling portion includes aluminum, and
the inside beam portion includes titanium or a titanium compound.

4. The electronic device according to claim 1,
wherein the ceiling portion includes
a first layer,
a second layer that is arranged on the opposite side of the first layer from the substrate and includes the same material as the first layer, and
an intermediate layer that is arranged between the first layer and the second layer and includes a material of which the thermal expansion rate is smaller than the thermal expansion rates of the first layer and the second layer.

5. The electronic device according to claim 4, further comprising:
an outside beam portion that is arranged between the intermediate layer and the second layer at a position where the outside beam portion overlaps with at least a part of the inside beam portion in a plan view.

6. The electronic device according to claim 1,
wherein the substrate includes a diaphragm portion that is disposed at a position where the diaphragm portion overlaps with the ceiling portion in a plan view and that is deformed in a flexural manner by the reception of pressure, and
the functional element is a sensor element that outputs an electrical signal from strain.

7. A physical quantity sensor comprising:
a substrate that includes a diaphragm portion which is deformed in a flexural manner by the reception of pressure;
a sensor element that is arranged on one face side of the diaphragm portion;
a wall portion that is arranged to surround the sensor element on the one face side of the substrate in a plan view of the substrate;
a ceiling portion that is arranged on the opposite side of the wall portion from the substrate and constitutes an inner space with the wall portion; and
an inside beam portion that is arranged on the substrate side of the ceiling portion and includes a material of which the thermal expansion rate is smaller than the thermal expansion rate of the ceiling portion.

8. A pressure sensor comprising:
the electronic device according to claim 1.

9. A pressure sensor comprising:
the electronic device according to claim 2.

10. A pressure sensor comprising:
the electronic device according to claim 3.

11. A vibrator comprising:
the electronic device according to claim 1.

12. A vibrator comprising:
the electronic device according to claim 2.

13. A vibrator comprising:
the electronic device according to claim 3.

14. An altimeter comprising:
the electronic device according to claim 1.

15. An altimeter comprising:
the electronic device according to claim 2.

16. An altimeter comprising:
the electronic device according to claim 3.

17. An electronic apparatus comprising:
the electronic device according to claim 1.

18. An electronic apparatus comprising:
the electronic device according to claim 2.

19. A moving object comprising:
the electronic device according to claim 1.

20. A moving object comprising:
the electronic device according to claim 2.
